(19) United States
(12) Patent Application Publication
(10) Pub. No.: US 2003/0070291 A1
(43) Pub. Date: Apr. 17, 2003

(54) Method for making a heat sink for a rectifier

(76) Inventor: Chun-Min Shih, Taipei (TW)

Correspondence Address: Keith Kline, PRO-TECHTOR INTERNATIONAL SERVICES, 20775 Norada Court, Saratoga, CA, 95070-3018, US

(21) Appl. No.: 09/977,583

(22) Filed: Oct. 12, 2001

(51) Int. Cl. H05K 3/30; H01K 3/10

(52) U.S. Cl. 29/841; 29/852; 29/832

(57) ABSTRACT

A method for making a heat sink of a rectifier has the steps of producing a heat sink of a rectifier; defining blind holes in the heat sink; implanting diodes in the blind holes; and encapsulating the blind holes with insulating material. With such an arrangement, the heat sink of the rectifier is able to dissipate heat of the rectifier directly and effectively and the assembly procedure of the rectifier is simplified.

### BACKGROUND OF THE INVENTION

1. Field of the Invention

This invention relates generally to a method for making a heat sink for a rectifier of an alternator, and more particularly to a method for making a heat sink for a rectifier with high performance of heat dissipation effect.

2. Description of Related Art

Conventionally, rectifiers for alternators are well known in the art. Diodes are secured to heat sink surfaces by soldering or brazing respectively. When alternating current goes through diodes, heat will concentrate in the neighborhood of diodes in the heat sinks because diodes only attach to the heat sinks with a small area. Therefore, most part of heat sink may not play a good role for dissipating heat caused by rectifying due to the uneven distribution of heat. In conventional rectifiers, diodes connect either anodes or cathodes to the surface of the heat sink respectively by soldering or brazing. Therefore, most of heat will concentrate near the diodes in the heat sinks due to a small contact surface between diodes and the heat sinks. The heat dissipating efficiency is also limited because of the uneven distribution of heat.

In addition, diodes are respectively secured to the heat sink with either anodes or cathodes by soldering or brazing in conventional rectifiers. The attachment between the heat sink and diodes is supported by one small attaching end. That will possibly cause collapse after a long period of vibration or an unexpected huge impact. Also, in today's rectifier, diodes respectively connected to the heat sink are secured on an external small surface of the heat sink. Due to these reasons, diodes take high risk being water infiltrated during raining season. Another way is using press-fit diodes to solve the drawbacks mentioned above. As shown in FIG. 3, the metal case (33) is used to package the die (32) with the nail connector (31). The combinations are called press-fit diodes (3). A die (32) is completely sunk into the metal case (33) so that water filtrating and particle contamination are kept away. The press-fit diodes (3) are installed into the holes (11) and holes (21) from the bottom of the first sink plate (1) and the second sink plate (2). Because the press-fit diodes (3) are completely pressed into the holes (11,21), heat caused by rectifying can be well distributed around the first sink plate (1) and the second sink plate (2). Because the die (32) is completely secured, the drawbacks described above can be solved. However, there are still some problems needed to be answered. The metal case (33) should be made by casting or lathing process. This makes the cost higher than before. The press-fit diodes (3) must be formed firstly before they are pressed into holes (11,21), this will increase labor cost. In addition, when press-fit diodes (3) are installed into holes (11,21), gaps exiting between metal case (33) and sink plates (1,2) are formed, this will significantly cut down the heat dissipating efficiency.

Furthermore, the conventional diodes involve manual assembly and then pressed into the heat sink of the rectifier, this will increase manufacture cost.

It is an objective of invention to provide a method for making a heat sink for a rectifier to mitigate and/or obviate the aforementioned problems.

### SUMMARY OF THE INVENTION

The primary objective of the invention is to provide a method for making a heat sink for a rectifier to averagely distribute heat produced by diodes. In the heat sink, blind holes are created for dice of diodes. Diodes can be formed and completely sunk into the main body of the heat sink, therefore the dice packaging of diodes can be achieved at the same time of rectifier manufacturing process. Because diodes are built into blind holes in the heat sink, the heat on diodes can be well distributed around the heat sink. Therefore, heat dissipation of heat sinks will be more efficient with the improved method when compared with the prior art.

Another objective of the present is to provide an improved heat sink in which blind holes are created for completely sinking dice of diodes. Dice of diodes can be completely placed into, and then an insulating material is filled into the spaces between the dice and the heat sinks. Therefore, during heat sink manufacturing, diodes packaging process is also accomplished in the same time. The new assembling method by packaging dice on the heat sink can avoid the fracture due to the small securing attachment between the diodes and the heat sink in conventional rectifiers.

Still another objective of the invention is that the dice of diodes are completely built in the blind holes and then sealed by the insulating material, water infiltrating and particle contamination can be prevented and diode protection is enhanced.

A further objective of the invention is that the packaging dice of diodes into blind holes in heat sink can eliminate lots of assembled parts on heat sinks in process line. The assembly process of rectifier will be simplified. The simplified assembly steps can reduce the cost in material of housing and therefore reduce manufacturing cost.

Other objects, advantages and novel features of invention will become more apparent from the following detailed description when taken in conjunction with accompanying drawings.

### BRIEF DESCRIPTION OF THE DRAWINGS

FIG. 1 is a flow chart showing the method for making a heat sink of a rectifier;

FIG. 2 is an exploded perspective view showing the structure made by the method of the invention; and

FIG. 3 is an exploded perspective view showing a conventional heat sink of a rectifier.

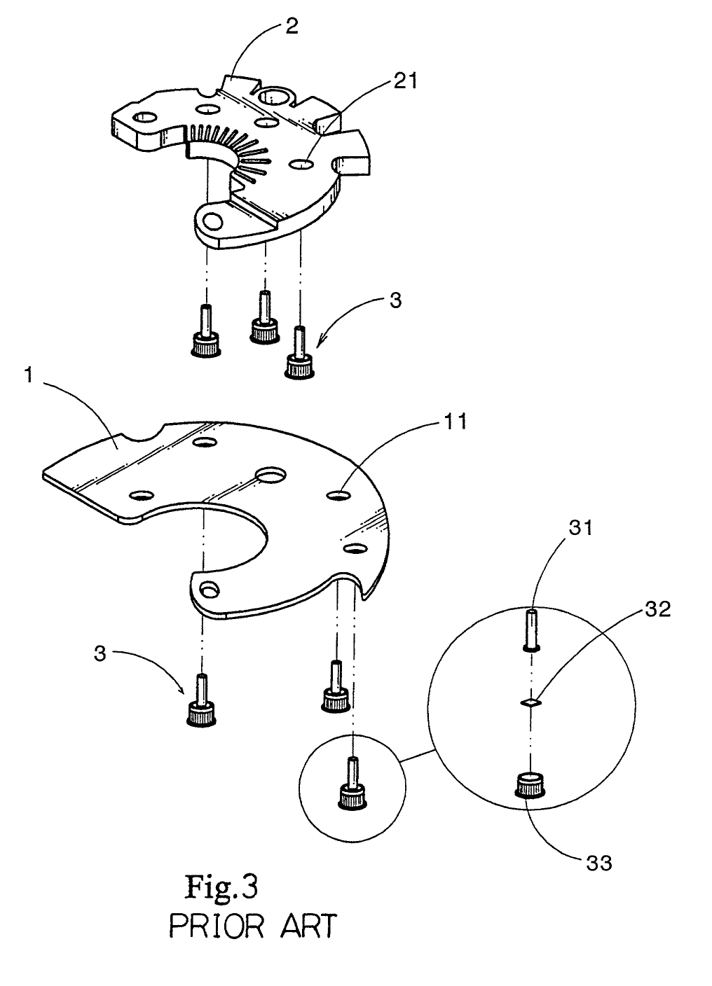

### DETAILED DESCRIPTION OF THE PREFERRED EMBODIMENT

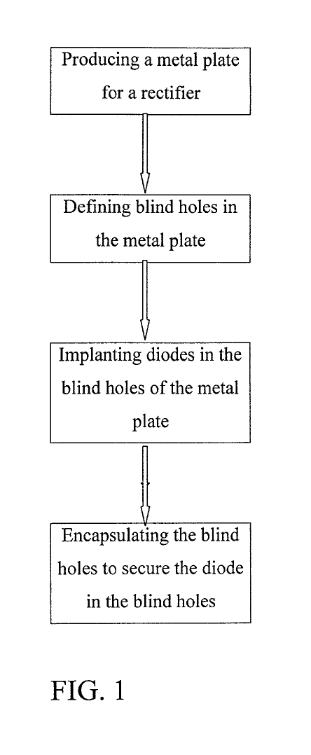

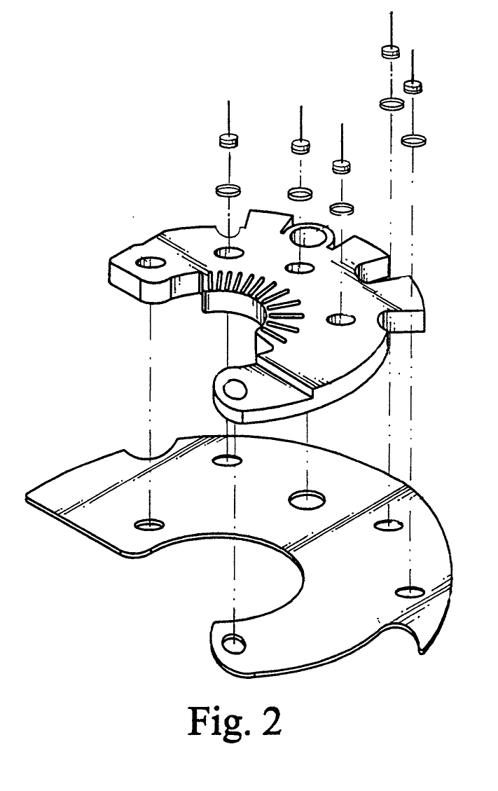

Referring to FIGS. 1 and 2, the method for making a heat sink of a rectifier comprises the steps of:

producing a metal plate for a rectifier;

defining blind holes in the heat sink;

implanting diodes in the blind holes; and

encapsulating the blind holes with insulating material.

It is to be noted that the heat sink of a rectifier is well known in the art, thus detailed description of the shape and the function thereof is omitted. However, the metal plate can be made of any metal with good heat conductivity, such as aluminum or the like.

After the metal plate of a rectifier is ready, any appropriate method known in the art is applied to define blind holes in the metal plate. Each blind holes has a dimension slightly larger than that of a diode so as to receive a corresponding diode in the blind hole. When the blind holes are defined in the metal plate, each of the diodes corresponding to the blind holes are then implanted into a corresponding one of the blind holes. After the diodes are implanted into the blind holes in the metal plate, an insulating material is used to encapsulate the blind holes to secure the diodes in the blind holes.

After all the procedures above are finished, an improved heat sink of a rectifier is accomplished. The method for making a heat sink of a rectifier has the following advantages:

1. low cost;

Because the method reduces a great deal of labor and material of housing, the fabrication cost is reduced.

2. direct heat conducting;

Because the diodes are encapsulated in the blind holes in the heat sink, the heat from the rectifier can be dissipated directly and effectively.

3. simplifying the assembly;

When compared with the prior art, the heat sink in accordance with the present invention receives the diodes directly therein. That is, the diodes are implanted in the heat sink, such that the assembly procedure is simplified.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for making a heat sink of a rectifier comprising the steps of:
producing a metal plate for a rectifier;
defining blind holes in the heat sink;
implanting diodes in the blind holes; and
encapsulating the blind holes with insulating material.

2. The method as claimed in claim 1, wherein the metal plate is made of aluminum.
